(19) United States
(12) Patent Application Publication
(10) Pub. No.: US 2026/0204876 A1
(43) Pub. Date: Jul. 16, 2026

(54) OPTICAL SEMICONDUCTOR DEVICE

(71) Applicant: Lumentum Operations LLC, San Jose, CA (US)

(72) Inventors: Yuga KODAMA, Tokyo (JP); Atsushi NAKAMURA, Komoro (JP); Masaru ONGA, Sagamihara (JP)

(21) Appl. No.: 19/247,375

(22) Filed: Jun. 24, 2025

(30) Foreign Application Priority Data
Jan. 15, 2025 (JP) 2025005466
Feb. 20, 2025 (JP) 2025026111

(51) Int. Cl. H01S 5/227; H01S 5/024; H01S 5/042; H01S 5/22

(52) U.S. Cl. CPC H01S 5/227; H01S 5/04256; H01S 5/2206; H01S 5/2222; H01S 5/02461

(57) ABSTRACT

A top surface of the first buried layer has a first sloped portion which slopes in a width direction of the mesa structure so as to be closer to the substrate as a distance from the mesa structure increases. A top surface of the second buried layer has a second sloped portion which slopes in the width direction so as to be closer to the substrate as a distance from the mesa structure increases. The electrode covers entirety of the first sloped portion and entirety of the second sloped portion.

### CROSS-REFERENCE TO RELATED APPLICATION

This Patent Application claims priority to Japan Patent Application No. JP2025-026111, filed on Feb. 20, 2025, and Japan Patent Application No. JP 2025-005466, filed on Jan. 15, 2025. The disclosure of the prior Applications are considered part of and are incorporated by reference into this Patent Application.

### TECHNICAL FIELD

The present invention relates to an optical semiconductor device.

### BACKGROUND

An optical semiconductor device is a device instrumental to optical communication. For example, a semiconductor laser can convert an applied electric signal into light and a semiconductor optical amplifier that amplifies light are in use. As another example, a semiconductor light-receiving device that converts light into an electric signal is also in use. A buried heterostructure (hereinafter referred to as a “BH structure”) is a type of structure used in some optical semiconductor devices. The BH structure is a structure in which a semiconductor layer is buried in each side of a mesa structure including an active layer or an absorption layer. The BH structure can have excellent characteristics such as high reliability, a high heat dissipation, and an aspect ratio of light that is close to 1.

### SUMMARY

Although a BH structure can have a heat dissipation property, it is often preferred to have an improved heat dissipation property in order to meet ever-increasing demands for high-density mounting, high-power driving, and the like. Further, ever higher output characteristics are demanded of a semiconductor laser. In order to meet this demand, drive currents are increasing and thus amounts of heat generation are also on the rise. A rise in temperature that occurs when a semiconductor laser is driven causes an increase in a threshold current, a drop in efficiency, and the like, and can consequently invite degradation of an optical output characteristic. Similarly, in optical semiconductor devices of other types as well, heat generation invites degradation of various characteristics and is accordingly undesirable.

Some implementations described herein provide an optical semiconductor device having an improved heat dissipation property (e.g., an excellent heat dissipation property).

In some implementations, an optical semiconductor device includes: a substrate; a mesa structure which protrudes from the substrate and extends in an extending direction parallel to the substrate, and which includes an active layer; a first buried layer of a semiconductor and a second buried layer of the semiconductor, the first buried layer being placed on a first side of the mesa structure in a section perpendicular to the extending direction, the second buried layer being placed on a second side of the mesa structure in the section; and an electrode which is formed on the mesa structure and which is partially placed on the first buried layer and the second buried layer, wherein a top surface of the first buried layer has a first sloped portion which slopes in a width direction of the mesa structure so as to be closer to the substrate as a distance from the mesa structure increases, wherein a top surface of the second buried layer has a second sloped portion which slopes in the width direction so as to be closer to the substrate as a distance from the mesa structure increases, wherein the electrode covers an entirety of the first sloped portion and an entirety of the second sloped portion.

### BRIEF DESCRIPTION OF THE DRAWINGS

FIG. 1 is a top view of an optical semiconductor device according to a first example implementation of the present invention.

FIG. 2 is a schematic sectional view of the optical semiconductor device illustrated in FIG. 1 that is taken along the line A-A.

FIG. 3 is a schematic sectional view for illustrating a shape of a buried layer.

FIG. 4 is a schematic sectional view of an optical semiconductor device according to Modification Example 1 of the first example implementation that is taken along the line A-A.

FIG. 5 is a schematic sectional view of an optical semiconductor device according to Modification Example 2 of the first example implementation that is taken along the line A-A.

FIG. 6 is a schematic sectional view of an optical semiconductor device according to a second example implementation of the present invention that is taken along the line A-A.

FIG. 7 is a top view of an optical semiconductor device according to a third example implementation of the present invention.

FIG. 8 is a schematic sectional view of the optical semiconductor device illustrated in FIG. 7 that is taken along the line A-A.

FIG. 9 is a schematic sectional view of an optical semiconductor device according to a modification example of the third example implementation that is taken along the line A-A.

### DETAILED DESCRIPTION

The following detailed description of example implementations refers to the accompanying drawings. The same reference numbers in different drawings may identify the same or similar elements. Elements may not be drawn to scale.

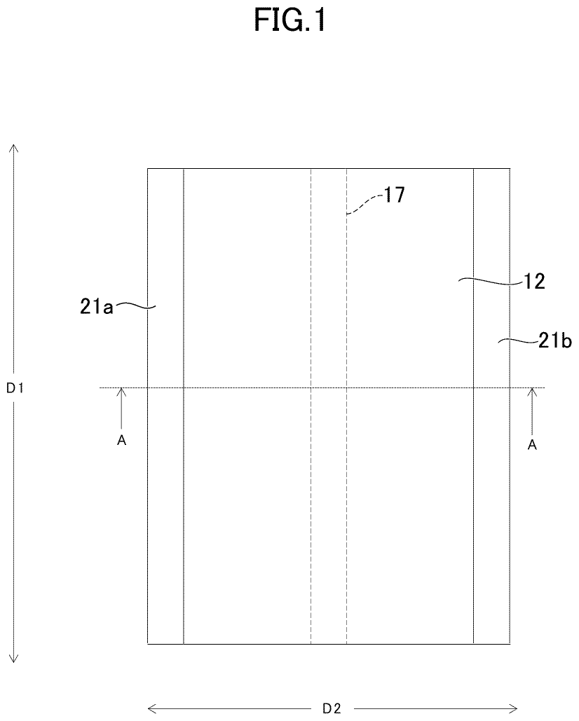

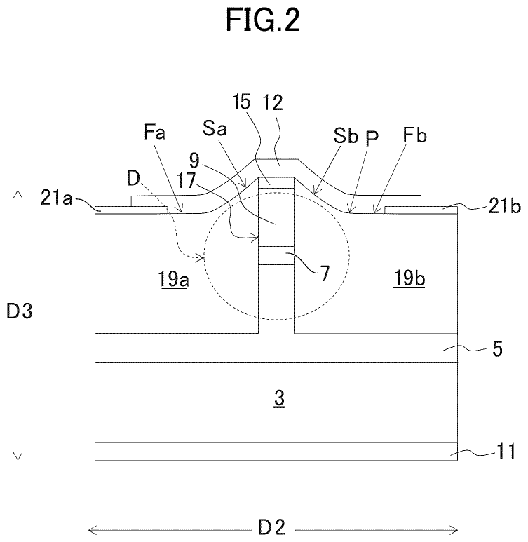

FIG. 1 is a top view of an optical semiconductor device according to a first example implementation of the present invention. FIG. 2 is a schematic sectional view of the optical semiconductor device illustrated in FIG. 1 that is taken along the line A-A. The optical semiconductor device according to the first example implementation is a semiconductor laser.

The optical semiconductor device includes a substrate 3, has a first electrode 11 on a rear surface of the substrate 3 and has a second electrode 12 on a front side of the substrate 3. The first electrode 11 and the second electrode 12 may be metal layers. Light may be emitted from end faces by injecting an electric current between the first electrode 11 and the second electrode 12. In the following, the term “end faces” means end faces of the optical semiconductor device in an extending direction D1 of a mesa structure 17 described later (end faces in a top-bottom direction of FIG. 1). In the first example implementation, a low-reflection end face coating film (not shown) may be formed on each of the end faces. The first example implementation may be modified so that a high-reflection end face coating film is formed on only one of the end faces.

The optical semiconductor device includes a semiconductor multilayer in which a first-conductivity-type cladding layer 5, an active layer 7, a second-conductivity-type cladding layer 9, and a second-conductivity-type contact layer 15 may be grown on the substrate 3 of a first conductivity type, in the stated order from the bottom upwards. A diffraction grating layer may be formed above or below the active layer 7. The first example implementation

may be modified so that the first-conductivity-type cladding layer 5 is not formed. In the first example implementation, the first-conductivity-type cladding layer 5 may be a semiconductor layer of the first conductivity type which is placed between the substrate 3 of the first conductivity type and the active layer 7. The active layer 7 may be formed from, for example, a multiple quantum well (MQW) layer. An optical confinement layer may be placed on each of, or one of, sides above and below the active layer 7. In the first example implementation, which takes a semiconductor laser as an example of the optical semiconductor device, the active layer 7 may be a layer that generates light. However, the active layer 7 is not limited to a layer that generates light. For example, the active layer may be a layer that functions as an absorption layer which converts light into electricity with application of a voltage. That is, “active layer” refers to a layer in which conversion between electricity and light takes place when a voltage is applied. The second-conductivity-type cladding layer 9 may be a second-conductivity-type semiconductor layer placed between the active layer 7 and the second-conductivity-type contact layer 15, and may be a plurality of layers instead of a single layer. In the following, “second-conductivity-type cladding layer 9” refers to a semiconductor layer or semiconductor layers of a second conductivity type that are placed above the active layer 7. That is, the semiconductor multilayer in the first example implementation may have a structure in which an active layer is sandwiched between a first-conductivity-type semiconductor layer and a second-conductivity-type semiconductor layer. The second-conductivity-type contact layer 15 may be placed in order to reduce contact resistance between the semiconductor layer and the metal layer (the second electrode 12). The second-conductivity-type contact layer 15 may have a resistivity lower than a resistivity of the second-conductivity-type cladding layer 9. The second-conductivity-type contact layer 15 may be higher in impurity concentration than the second-conductivity-type cladding layer 9. In the first example implementation, the first conductivity type and the second conductivity type are an “n” type and a “p” type, respectively, but the “p” type and the “n” type may be reversed with each other.

The optical semiconductor device includes the mesa structure 17 which protrudes from the substrate 3. A lowermost part of the mesa structure 17 may be configured from a part of the first-conductivity-type cladding layer 5. The mesa structure 17 extends in the extending direction D1 parallel to the substrate 3, and reaches both end faces. In FIG. 1, boundaries of the mesa structure 17, to a left buried layer 19a and to a right buried layer 19b, which are described later, are indicated by broken lines. The mesa structure 17 may include the active layer 7, the second-conductivity-type cladding layer 9, and the second-conductivity-type contact layer 15. In the mesa structure 17, the part of the first-conductivity-type cladding layer 5, the active layer 7, the second-conductivity-type cladding layer 9, and the second-conductivity-type contact layer 15 may be grown in the stated order from the bottom upwards. In the first example implementation, the second-conductivity-type contact layer 15 may be an uppermost layer of the mesa structure 17.

In a section perpendicular to the extending direction D1, the left buried layer 19a (a first buried layer) which is a semiconductor may be placed on a left side (first side) of the mesa structure 17, and the right buried layer 19b (a second buried layer) which is a semiconductor may be placed on a right side (second side) of the mesa structure 17. The left buried layer 19a and the right buried layer 19b may have a multilayer structure including a semi-insulating semiconductor layer and a semiconductor layer of the first-conductivity type and the second conductivity type, or a multilayer structure including a semi-insulating semiconductor layer and a first-conductivity-type semiconductor layer, and a second-conductivity-type semiconductor layer. Desirably, a material that forms main regions of the left buried layer 19a and the right buried layer 19b may be the same material that forms the first-conductivity-type cladding layer 5 and the second-conductivity-type cladding layer 9. An example of such a material is InP. Here, “the same material” indicates that a basic composition (here, InP) excluding a material that is used for doping is the same.

A top surface of the left buried layer 19a may include a left sloped portion Sa (first sloped portion) which slopes in a width direction D2 of the mesa structure 17 so as to be closer to the substrate 3 as a distance from the mesa structure 17 increases, and a left flat portion (first flat portion) Fa which is substantially parallel to a top surface of the substrate 3 and which continues to the left sloped portion Sa. A top surface of the right buried layer 19b may include a right sloped portion Sb (a second sloped portion) which slopes in the width direction D2 of the mesa structure 17 so as to be closer to the substrate 3 as a distance from the mesa structure 17 increases, and a right flat portion (second flat portion) Fb which is substantially parallel to the top surface of the substrate 3 and which continues to the right sloped portion Sb. In a height direction (a normal direction of the substrate 3) D3 of the mesa structure 17, a height of the top surface of the left buried layer 19a in the left flat portion Fa from the substrate 3 may be lower than a height of the top surface of the mesa structure 17 from the substrate 3 (the same applies to the right flat portion Fb). In FIG. 2, the left sloped portion Sa and the right sloped portion Sb drop with the top surface of the mesa structure 17 (a top surface of the second-conductivity-type contact layer 15) as a starting point, but are not limited thereto.

The left sloped portion Sa and the right sloped portion Sb may be configured from combinations of a straight line and a curve line. A height of the top surface of the left buried layer 19a in the left sloped portion Sa from the substrate 3 decreases generally in a monotonic manner (the same applies to the right sloped portion Sb) but, because the left buried layer 19a and the right buried layer 19b may be formed by crystal growth, the left sloped portion Sa and the right sloped portion Sb may include some undulations. At least one of the left sloped portion Sa and the right sloped portion Sb may include one or more level differences.

The left flat portion Fa and the right flat portion Fb may be parts of the top surfaces of the left buried layer 19a and the right buried layer 19b, respectively, that are distanced from the mesa structure 17 and that are substantially parallel to the surface of the substrate 3. In the width direction D2, the left flat portion Fa continues to the left sloped portion Sa, and the right flat portion Fb continues to the right sloped portion Sb. The left buried layer 19a and the right buried layer 19b may be formed by crystal growth and, accordingly, there may be some undulations in the flat portions F. However, even when heights of the left flat portion Fa and the right flat portion Fb fluctuate to some degree, the left flat portion Fa and the right flat portion Fb may be placed at positions lower than the top surface of the mesa structure 17 with respect to the substrate 3. The left flat portion Fa may be defined to be a flat part adjacent to the left sloped portion Sa, out of a part of the top surface of the left buried layer 19a that continues to the left sloped portion Sa (the right flat portion Fb may be similarly defined). A plurality of crystal growth processes and a plurality of etching processes may may have been executed by the time the left buried layer 19a and the right buried layer 19b are formed. When it is the case, a surface to serve as a foundation for crystal growth of the left buried layer 19a and the right buried layer 19b (here, a top surface of the first-conductivity-type cladding layer 5) may not be flat. Specifically, a height of the top surface of the first-conductivity-type cladding layer 5 from the substrate 3 may differ between a region immediately beside the mesa structure 17 and a region distant from the mesa structure 17. When it is the case, there is a possibility that the top surfaces of the left buried layer 19a and the right buried layer 19b formed on the top surface of the first-conductivity-type cladding layer 5 have a shape different between the region immediately beside the mesa structure 17 and the region distant from the mesa structure 17 as well. That is, the top surfaces of the left buried layer 19a and the right buried layer 19b may be flat in the region immediately beside the mesa structure 17 but may not be flat in the region distant from the mesa structure 17. However, in the first example implementation, it is not a requirement for the top surfaces of the left buried layer 19a and the right buried layer 19b to have a flat shape in regions that are too far from the mesa structure 17 to affect a light distribution D described later. For that reason, the left flat portion Fa may be defined to be a flat part adjacent to the left sloped portion Sa, out of the top surface of the left buried layer 19a (the right flat portion Fb may be similarly defined).

A border between the left sloped portion Sa and the left flat portion Fa may not be distinct (the same applies to the right sloped portion Sb and the right flat portion Fb). In the first example implementation, the left sloped portion Sa may be a part that slopes in the width direction D2 so as to be closer to the substrate 3 as the distance from the mesa structure 17 increases, and may be defined to be a part from a point at which a thickness of the left buried layer 19a in the height direction D3 is thickest to a point at which that thickness is thinnest (the right sloped portion Sb may be similarly defined). Here, the point at which each of the thicknesses of the left buried layer 19a and the right buried layer 19b in the height direction D3 is thinnest may be referred to as “lowermost point P.” Although the left sloped portion Sa and the left flat portion Fa are smoothly connected to each other in FIG. 2, how the two portions are connected is not limited thereto, and the top surface of the left buried layer 19a may be

shaped so as to slope from the top surface of the mesa structure 17 to the lowermost point P, then slope upward once, and continue to the left flat portion Fa (the same applies to the right sloped portion Sb and the right flat portion Fb). Widths of the left sloped portion Sa and the right sloped portion Sb in the width direction D2 are approximately from a few micrometers to 5 micrometers, depending on the thicknesses of the left buried layer 19a and the right buried layer 19b in the height direction D3.

A left insulating film (first insulating film) 21a may be placed in a part of the top surface of the left buried layer 19a, and a right insulating film (second insulating film) 21b may be placed in a part of the top surface of the right buried layer 19b. No parts of the left insulating film 21a and the right insulating film 21b may be placed on the top surface of the mesa structure 17 and, accordingly, the second-conductivity-type contact layer 15 and the second electrode 12 may be in contact with each other. The left insulating film 21a and the right insulating film 21b may be formed from, for example, silicon oxide films or silicon nitride films. In the first example implementation, the left insulating film 21a may be placed in the left flat portion Fa but not in the left sloped portion Sa (the right insulating film 21b may be placed in a similar manner).

The first electrode 11 may be placed on a wide stretch of the rear surface of the substrate 3. In the first example implementation, the first electrode 11 may be placed so as to reach both ends of the substrate 3 in the width direction D2, but is not limited thereto. For example, the first electrode 11 may be modified so as not to reach both ends of the substrate 3 in the width direction D2. The second electrode 12 may have a multilayer structure that includes at least a Au layer. For example, the second electrode 12 may have a three-layer layer structure in which layers of Ti, Pt, and Au are grown in order from a side on which the second-conductivity-type contact layer 15 is located (from the bottom upwards). This configuration is merely an example. The second electrode 12 may be placed so as to cover at least an entirety of the left sloped portion Sa and an entirety of the right sloped portion Sb which are placed on each side of the mesa structure 17 and sandwich the mesa structure 17. In the first example implementation, the second electrode 12 is placed on top of a part of the left flat portion Fa and a part of the right flat portion Fb as well. The second electrode 12 may include a left sloped electrode portion which slopes along the left sloped portion Sa and a left flat electrode portion which may be flat along the left flat portion Fa. Although the second electrode 12 directly covers an entirety of the left sloped portion Sa and the right sloped portion Sb in the first example implementation, the left sloped portion Sa and the right sloped portion Sb may be covered indirectly with the second electrode 12. That is, another member may be interposed between the second electrode 12 and the left sloped portion Sa (the same applies to the right sloped portion Sb). In that case, the another member may include a part that slopes along the left sloped portion Sa as well.

When the optical semiconductor device is driven, that is, when a voltage is applied between the first electrode 11 and the second electrode 12, the mesa structure 17 becomes a source of heat generation. Among a plurality of factors for the heat generation, the active layer 7, in particular, is a source that generates a very large amount of heat. The heat generated by the active layer 7 may be dissipated via the semiconductor layers around the active layer 7. A distance from the active layer 7 to the first electrode 11 is generally several times longer than a distance from the active layer 7 to the second electrode 12. Accordingly, a larger amount of heat may be dissipated from the second electrode 12 side. The second electrode 12 may be a metal layer and, having an excellent heat conductivity, may be a fine heat dissipation member. A heat dissipation property may be accordingly improved by closing a gap between a heat generator (the active layer 7) and the heat dissipation member (the second electrode 12), and an optical semiconductor device having excellent high-temperature characteristics can thus be achieved. In the first example implementation, as illustrated in FIG. 2, the left buried layer 19a and the right buried layer 19b include the left sloped portion Sa and the right sloped portion Sb, respectively, and the second electrode 12 is placed above the left sloped portion Sa and the right sloped portion Sb. Accordingly, compared to another optical semiconductor device (e.g., with a gap from an active layer to an electrode), the optical semiconductor device according to the first example implementation may have a superior heat dissipation property because of the close gap from the active layer 7 to the second electrode 12. In some cases, an optical semiconductor has a buried layer that includes a sloped portion, but no electrode is placed in the sloped portion. In contrast, the optical semiconductor device according to the first example implementation has the second electrode 12 placed above the entirety of the left sloped portion Sa and the entirety of the right sloped portion Sb, and is accordingly superior in heat dissipation property.

Further thinning of the left buried layer 19a and the right buried layer 19b may further improve the heat dissipation property. However, this may not desirable from a viewpoint of optical characteristics. In FIG. 2, an outer edge of the light distribution D of a light wave guided through the mesa structure 17 is indicated by the broken line. The light distribution D spreads in a circular pattern with the active layer 7 at a center. The light distribution D has a generally elliptical shape. In the light distribution D, light intensity may be highest at the center and decreases toward a periphery. In FIG. 2, regions in which values up through 2σ of a light intensity distribution are obtained are illustrated as the light distribution D. In the second-conductivity-type contact layer 15 which may have a high impurity concentration, a loss of light may be large. A thickness of the second-conductivity-type cladding layer 9 in the height direction D3 may be accordingly set so that overlap between the outer edge of the light distribution D and the second-conductivity-type contact layer 15 is avoided. The second-conductivity-type cladding layer 9 may be another factor for a loss of light and, when being thick in the height direction D3, raises resistance. Accordingly, the second-conductivity-type cladding layer 9 may be also desired to be thin. However, in order to avoid the loss of light due to the second-conductivity-type contact layer 15, the thickness of the second-conductivity-type cladding layer 9 in the height direction D3 may be intentionally set to a thickness that is thick to some degree. Now, a case in which the left buried layer 19a and the right buried layer 19b are set to the same height as the height of the mesa structure 17 is discussed. That is, the left buried layer 19a and the right buried layer 19b may be assumed to have no left sloped portion Sa and no right sloped portion Sb. With this structure, the light distribution D may be naturally contained within the semiconductor layers around the active layer 7, and maintains a favorable light distribution shape. When the left buried layer 19a and the right buried layer 19b are started to be thinned from this state, that is, when the left sloped portion Sa and the right sloped portion Sb are formed and brought closer to side surfaces of the mesa structure 17, the outer edge of the light distribution D overlaps the left sloped portion Sa and the right sloped portion Sb at certain points. Strictly speaking, due to a difference in refractive index between the left buried layer 19a and the right buried layer 19b (semiconductors) and a surrounding environment (for example, air), the light distribution D changes its shape so as to be confined within the semiconductor layers. Specifically, the light distribution D shifts to a vertically long elliptical shape. The change in shape of the light distribution D invites a drop in efficiency of coupling to an optical system (a lens or a waveguide) into which output light from the optical semiconductor device is input, and is accordingly undesirable.

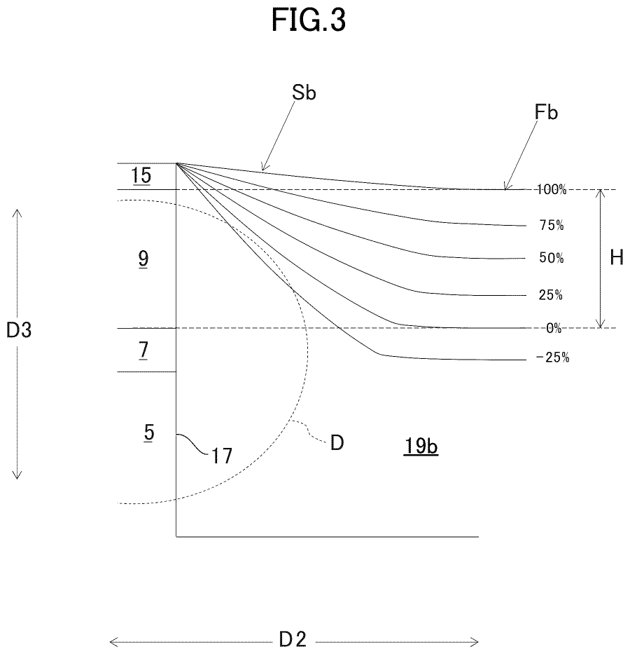

The first example implementation addresses the issue by setting the thicknesses of the left buried layer 19a and the right buried layer 19b in the height direction D3 within a range in which the light distribution D is not affected. A positional relationship of the left sloped portion Sa and the left flat portion Fa may be determined by crystal growth (the same applies to the right sloped portion Sb and the right flat portion Fb). Changes in top-surface shape of the left buried layer 19a and the right buried layer 19b are illustrated in FIG. 3. Although only a shape to the right of the mesa structure 17 is illustrated in FIG. 3 for simpler description, a shape to the left of the mesa structure 17 is substantially the same. Illustration of the second electrode 12 is also omitted in FIG. 3.

As illustrated in FIG. 3, a distance of the right sloped portion Sb from the side surface of the mesa structure 17 and the outer edge of the light distribution D increases as a height of the right buried layer 19b in the right flat portion Fb becomes lower relative to the substrate 3. In FIG. 3, the outer edge of the light distribution D that is observed when the top surface of the right buried layer 19b in the right flat portion Fb is flush with the top surface of the mesa structure 17 relative to the substrate 3 is indicated by a circle of a broken line. As described above, the gap between the active layer 7 and the second-conductivity-type contact layer 15 may be set so that overlap with the outer edge of the light distribution D is avoided. A distance (height) between a top surface of the active layer 7 and a bottom surface of the second-conductivity-type contact layer 15 in the height direction D3 is given as H. For example, the solid line in FIG. 3 beside which “0%” is displayed indicates a top-surface shape of the right buried layer 19b that is observed when the top surface of the right buried layer 19b in the right flat portion Fb is flush with the top surface of the active layer 7 in the height direction D3. Similarly, the solid line in FIG. 3 beside which “100%” is displayed indicates the top-surface shape of the right buried layer 19b that is observed when the top surface of the right buried layer 19b in the right flat portion Fb is flush with a bottom surface of the second-conductivity-type contact layer 15 in the height direction D3. The solid line beside which “25%” is displayed indicates the top-surface shape of the right buried layer 19b that is observed when the top surface of the right buried layer 19b in the right flat portion Fb is positioned in the height direction D3 at a point that is 25% of the height H with the top surface of the active layer 7 as a base point. The same applies to the rest of the numerical values.

As is clear from FIG. 3, when the top surface of the right buried layer 19b in the right flat portion Fb positioned at a height that is 0% or more of the height H with the top surface of the active layer 7 as a base point, overlap of the right sloped portion Sb with the outer edge of the light distribution D is avoided, and the light distribution D retains the favorable shape. When this is joined by minimization of the distance between the active layer 7 and a part of the second electrode 12 that is placed above the right sloped portion Sb, to an extent that does not affect the light distribution D, a most excellent heat dissipation property is achieved. In contrast, when the top surface of the right buried layer 19b in the right flat portion Fb is placed lower than the point that is 0% of the height H with the top surface of the active layer 7 as a base point (for example, a point that is −25%), the light distribution D may be affected and the placement may be accordingly undesirable. When the top surface of the right buried layer 19b in the right flat portion Fb is at a higher position, the right sloped portion Sb is distanced farther from the outer edge of the light distribution D and the light distribution D may be accordingly affected less, but the heat dissipation property deteriorates.

Accordingly, in some implementations, a preferred heat dissipation property may be obtained when the top surface of the right buried layer 19b in the right flat portion Fb is positioned at a point that is 50% or less of the height H with the top surface of the active layer 7 as a base point. The shape of the light distribution D varies depending on an optical confinement ratio of the active layer 7 and other factors. For example, there may be a case in which a diameter of the light distribution D is shorter than diameters illustrated in FIG. 2 and FIG. 3. However, in that case also, the relationship of the top-surface shape of the right buried layer 19b that is illustrated in FIG. 3 is basically the same because the height H decreases as well, and, by placing the top surface of the right buried layer 19b in the right flat portion Fb at a point that is 0% or more and 50% or less of the height H (0H or more and 0.5H or less with the top surface of the active layer 7 as a base point), the heat dissipation property may be improved with an adverse effect to the light distribution D suppressed. When production tolerance, a difference in aspect ratio of light distributions, securement of an even more excellent heat dissipation property, and other factors are taken into consideration, it may be more preferred to place the top surface of the right buried layer 19b in the right flat portion Fb at a point that is 10% or more and 30% or less of the height H (0.1H or more and 0.3H or less) with the top surface of the active layer 7 as a base point.

Another feature of the first example implementation is that no part of the left insulating film 21a may be placed in the left sloped portion Sa (the same applies to the right sloped portion Sb and the right insulating film 21b). The left insulating film 21a may have a low heat conductivity and accordingly hinders heat dissipation. The left insulating film 21a may be particularly low in heat conductivity when being formed from a silicon oxide. Accordingly, in the first example implementation, no part of the left insulating film 21a may be placed in the left sloped portion Sa which serves as a heat dissipation path in order to obtain a maximum effect of the heat dissipation property. However, a very thin insulating film, a silicon nitride film which has a relatively high heat conductivity, or the like is allowed to be placed in the left sloped portion Sa.

As described above, in the first example implementation, the left sloped portion Sa and the right sloped portion Sb may be formed in the left buried layer 19a and the right buried layer 19b, respectively, and the second electrode 12 which serves as a heat dissipation member may be placed there, to thereby achieve the optical semiconductor device having an excellent heat dissipation property. The heat dissipation property may be enhanced by, as described above, covering an entirety of the left sloped portion Sa and an entirety of the right sloped portion Sb in the width direction D2 with the second electrode 12. The heat dissipation property is maximized by covering the entirety of the left sloped portion Sa and the entirety of the right sloped portion Sb in the extending direction D1 as well. However, it is not always required to cover the entirety of the left sloped portion Sa and the entirety of the right sloped portion Sb in the extending direction D1 with the second electrode 12. For example, in a chip dicing process for dicing a wafer that has completed a wafer process into respective devices, the second electrode 12 may be preferred to be placed so as to be absent in a region that serves as the emission end face. Accordingly, the first example implementation may be modified so that no parts of the second electrode 12 are placed near the emission end face and the end face on the opposite side (the end face in the extending direction D1). When the region in which no part of the second electrode 12 is placed increases in size, the heat dissipation property naturally deteriorates. When the viewpoint of heat dissipation property is added, it may be preferred for the second electrode 12 to cover 80% or more of each of the left sloped portion Sa and the right sloped portion Sb in the extending direction D1. The second electrode 12 may be placed on the top surface of the mesa structure 17 as well, but is not always required to cover the entirety of the top surface of the mesa structure 17. For example, near end faces of the mesa structure 17, there may be parts in which the second electrode 12 is not placed above the mesa structure 17.

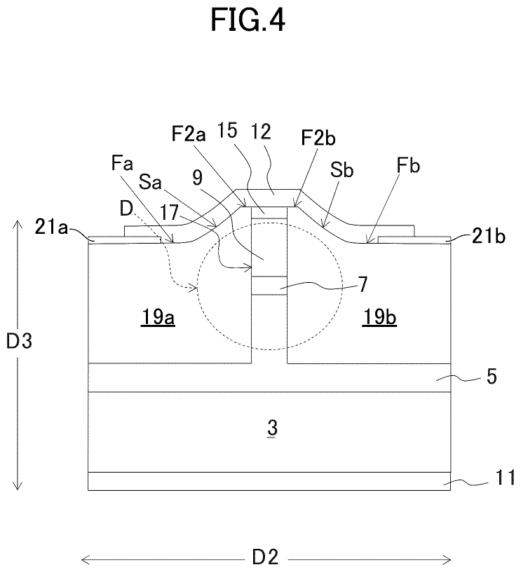

FIG. 4 is a schematic sectional view of an optical semiconductor device according to Modification Example 1 of the first example implementation that is taken along the line A-A of FIG. 1. A difference from the first example implementation is the shape of the top surfaces of the left buried layer 19a and the right buried layer 19b.

The top surface of the left buried layer 19a in Modification Example 1 may include a left sub-flat portion (first sub-flat portion) F2a which continues to the top surface of the mesa structure 17 in the width direction D2. The top surface of the right buried layer 19b may include a right sub-flat portion (second sub-flat portion) F2b which continues to the top surface of the mesa structure 17 in the width direction D2. The left sloped portion Sa and the left flat portion Fa may be formed so as to continue from the left sub-flat portion F2a. The left sub-flat portion F2a may be a surface substantially parallel to the surface of the substrate 3, as the left flat portion Fa is. A height of the left sub-flat portion F2a in the height direction D3 relative to the substrate 3 may be substantially the same as the height of the top surface of the mesa structure 17 in the height direction D3. For example, in a case in which an inclination angle of the left sloped portion Sa is sharp compared to the first example implementation, the left sloped portion Sa may be distanced from the outer edge of the light distribution D by forming the left sub-flat portion F2a, and can consequently be brought closer to the mesa structure 17 without affecting the light distribution D. The description given above about the left sub-flat portion F2a applies also to the right sub-flat portion F2b.

The left sub-flat portion F2a and the right sub-flat portion F2b may be formed by adjusting a mask size used when the left buried layer 19a and the right buried layer 19b are formed. for example, a mask may be placed on the mesa structure 17 when the left buried layer 19a and the right buried layer 19b are formed. The left sub-flat portion F2a and the right sub-flat portion F2b may be formed by making a width of the mask in the width direction D2 wider than a width of the mesa structure 17 in the width direction D2. However, when the mask width is too wide, the mask may become eaves that hinder the left buried layer 19a and the right buried layer 19b from being formed on the side surfaces of the mesa structure 17, particularly in parts close to the top surface of the mesa structure 17. In addition, the mask that is too wide widens a gap between the mesa structure 17 and the left sloped portion Sa (the right sloped portion Sb) to cause deterioration of the heat dissipation property. It is accordingly desired to keep a width of each of the left sub-flat portion F2a and the right sub-flat portion F2b in the width direction D2 to half the width of the mesa structure 17 in the width direction D2 or less.

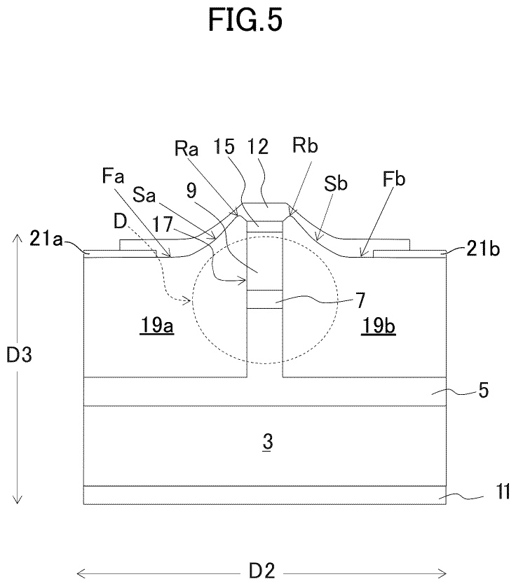

FIG. 5 is a schematic sectional view of an optical semiconductor device according to Modification Example 2 of the first example implementation that is taken along the line A-A of FIG. 1. A difference from the first example implementation is the shape of the top surfaces of the left buried layer 19a and the right buried layer 19b.

The left buried layer 19a in Modification Example 2 may include a left protruding portion (first protruding portion) Ra which continues to the top surface of the mesa structure 17 and protrudes from the substrate 3. The right buried layer 19b may include a right protruding portion (second protruding portion) Rb which continues to the top surface of the mesa structure 17 and protrudes from the substrate 3. The left sloped portion Sa and the left flat portion Fa may be formed so as to continue from the left protruding portion Ra (the same applies to the right protruding portion Rb). The left protruding portion Ra and and the right protruding portion Rb may be formed as illustrated in FIG. 5 when, for example, a mask placed on the mesa structure 17 in forming of the left buried layer 19a and the right buried layer 19b has a width in the width direction D2 that matches the width of the mesa structure 17 in the width direction D2. In a case in which the left protruding portion Ra and the right protruding portion Rb are too large, the left sloped portion Sa and the right sloped portion Sb may be distanced from the mesa structure 17, with the result that the heat dissipation property deteriorates. Accordingly, a thickness of each of the left protruding portion Ra and the right protruding portion Rb in the height direction D3 is desired to be thinner than a thickness of the second-conductivity-type contact layer 15 in the height direction D3. Here, the thickness of each of the left protruding portion Ra and the right protruding portion Rb is defined to be a gap from the top surface of the mesa structure 17 to a highest point of each of the left protruding portion Ra and the right protruding portion Rb.

As described above, the left sloped portion Sa and the right sloped portion Sb do not always have the top surface of the mesa structure 17 as a starting point. The left sloped portion Sa may be a part of the top surface of the buried layer 19 that slopes in the width direction D2 so as to be closer to the substrate 3 as the distance from the mesa structure 17 increases (the right sloped portion Sb may be similarly defined). The left sloped portion Sa may be also defined to be a part closest to the mesa structure 17 out of a part of the top surface of the left buried layer 19a that slopes in the width direction D2 so as to be closer to

the substrate 3 as the distance from the mesa structure 17 increases (the right sloped portion Sb may be similarly defined).

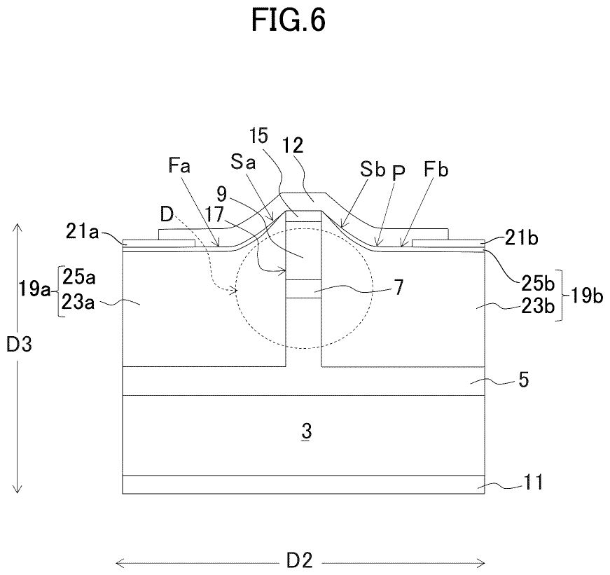

FIG. 6 is a sectional view for schematically illustrating a section of an optical semiconductor device according to a second example implementation of the present invention. The section corresponds to the A-A section of FIG. 1. A difference from the first example implementation is the structure of the left buried layer 19a and the right buried layer 19b.

The left buried layer 19a in the second example implementation includes a left current block layer (first current block layer) 23a and a left diffusion prevention layer (first diffusion prevention layer) 25a. The right buried layer 19b includes a right current block layer (second current block layer) 23b and a right diffusion prevention layer (second diffusion prevention layer) 25b. The left current block layer 23a and the right current block layer 23b may be the same in essence as the left buried layer 19a and the right buried layer 19b, respectively, that are described in the first example implementation. That is, the left current block layer 23a and the right current block layer 23b may be high-resistance semiconductor layers for concentrating a current in the mesa structure 17. Specifically, the left current block layer 23a and the right current block layer 23b may be formed from semi-insulating InP as in the first example implementation. The left current block layer 23a and the right current block layer 23b may be conductive multilayer structures including semiconductor layers. The left diffusion prevention layer 25a and the right diffusion prevention layer 25b may be uppermost layers of the left buried layer 19a and the right buried layer 19b, respectively. A diffusion constant of Au in each of the left diffusion prevention layer 25a and the right diffusion prevention layer 25b may be smaller than a diffusion constant of Au in each of the left current block layer 23a and the right current block layer 23b. When the left current block layer 23a and the right current block layer 23b are formed from InP, for example, the left diffusion prevention layer 25a and the right diffusion prevention layer 25b may be formed from at least one of such materials as InGaAs, InAlAs, InGaAsP, and InGaAlAs. The left diffusion prevention layer 25a and the right diffusion prevention layer 25b may each be a single layer formed from one of those materials, or a plurality of layers formed from two or more of those materials. The left diffusion prevention layer 25a and the right diffusion prevention layer 25b may be undoped layers.

In the second example implementation also, no parts of the left insulating film 21a and the right insulating film 21b may be placed on the left sloped portion Sa and the right sloped portion Sb. Consequently, Au contained in the Au layer out of the layers that form the second electrode 12 penetrates the Ti layer and the Pt layer which are placed under the Au layer and reaches the left buried layer 19a and the right buried layer 19b in some cases. The element Au has a property of diffusing in InP from which the left current block layer 23a and the right current block layer 23b (the left buried layer 19a and the right buried layer 19b) may be formed. The diffusion of Au contained in the second electrode 12 to the left current block layer 23a and the right current block layer 23b may invite degradation of characteristics. In this regard, the left diffusion prevention layer 25a and the right diffusion prevention layer 25b formed from at least one of InGaAs, InGaAsP, InGaAlAs, and InAlAs may be placed on the left current block layer 23a and the right current block layer 23b, respectively, in the second example implementation. Diffusion constants of Au in InGaAs, InGaAsP, InGaAlAs, and InAlAs may be smaller than the diffusion constant of Au in InP. Accordingly, by placing the left diffusion prevention layer 25a and the right diffusion prevention layer 25b which are formed from at least one of those materials, diffusion of Au to the left current block layer 23a and the right current block layer 23b which are formed from InP can be prevented.

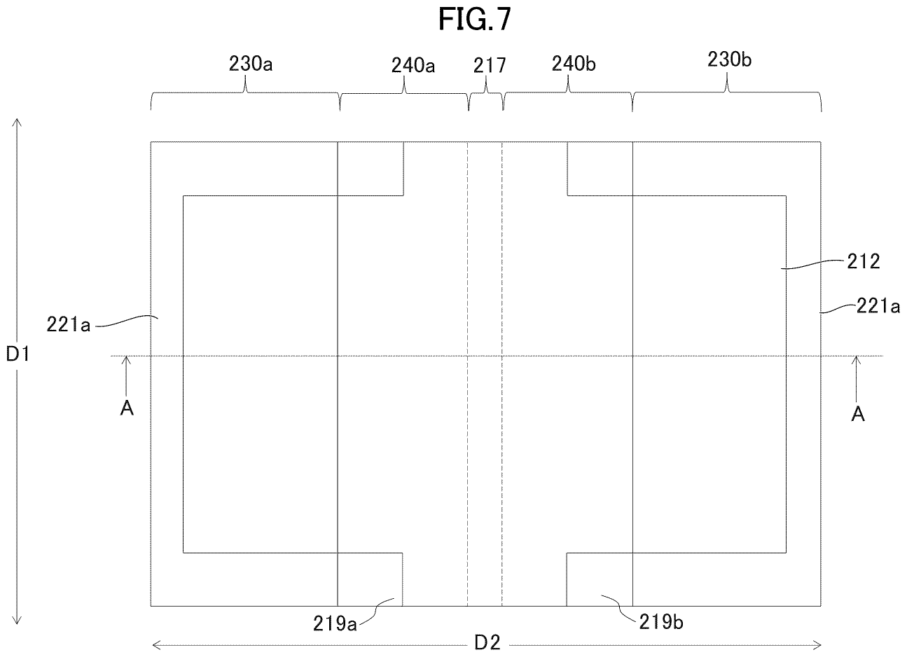

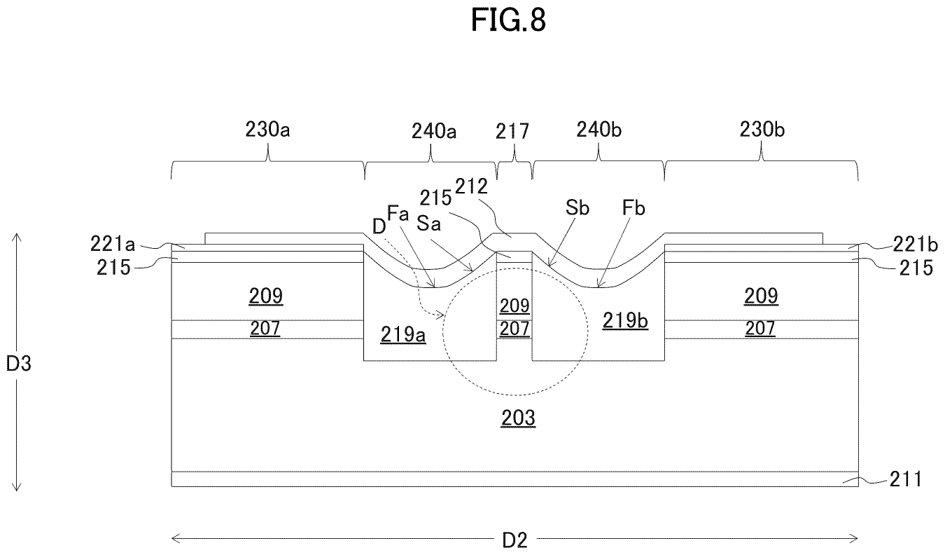

FIG. 7 is a top view of an optical semiconductor device according to a third example implementation of the present invention. FIG. 8 is a schematic sectional view of the optical semiconductor device illustrated in FIG. 7 that is taken along the line A-A. The optical semiconductor device according to the third example implementation is a semiconductor optical amplifier.

The optical semiconductor device includes a substrate 203, has a first electrode 211 on a rear surface of the substrate 203 and has a second electrode 212 on a front side thereof. The first electrode 211 and the second electrode 212 are metal layers. The optical semiconductor device includes a mesa structure 217 extending in the extending direction D1, amplifies an optical signal input from an end face on one side in the extending direction D1, and outputs the amplified optical signal from an end face on an opposite side. In the third example implementation, in which a current is injected between the first electrode 211 and the second electrode 212 for optical amplification, a low-reflection end face coating film (not shown) is formed on each of the end faces.

The optical semiconductor device includes a semiconductor multilayer in which an active layer 207, a second-conductivity-type cladding layer 209, and a second-conductivity-type contact layer 215 may be grown on the substrate 203 of the first conductivity type, in the stated order from the bottom upwards. A diffraction grating layer may be formed above or below the active layer 207. In the third example implementation, the substrate 203 functions as the first-conductivity-type cladding layer 5. However, a first-conductivity-type cladding layer may be placed between the substrate 203 and the active layer 207 as a separate layer as in the first example implementation. The active layer 207 may be formed from, for example, a multiple quantum well layer. An optical confinement layer may be placed on each of, or one of, sides above and below the multiple quantum well layer. The second-conductivity-type cladding layer 209 may be a second-conductivity-type semiconductor layer placed between the active layer 207 and the second-conductivity-type contact layer 215, and may be a plurality of layers instead of a single layer. As in the first example implementation, the optical semiconductor device according to the third example implementation may have a structure in which an active layer is sandwiched between a first-conductivity-type semiconductor layer and a second-conductivity-type semiconductor layer. The second-conductivity-type contact layer 215 may be placed in order to reduce contact resistance between the semiconductor layer and the metal layer (the second electrode 212). The second-conductivity-type contact layer 215 may have a resistivity lower than a resistivity of the second-conductivity-type cladding layer 209. The second-conductivity-type contact layer 215 may be higher in impurity concentration than the second-conductivity-type cladding layer 209. In the third example implementation, the first conductivity type and the second conductivity type may be an “n” type and a “p” type, respectively.

The optical semiconductor device may include the mesa structure 217. A lowermost part of the mesa structure 217 may be configured from a part of the substrate 203. The mesa structure 217 extends in the extending direction D1, and reaches both end faces. The mesa structure 217 may include the active layer 207, the second-conductivity-type cladding layer 209, and the second-conductivity-type contact layer 215. In the mesa structure 217, the part of the substrate 203, the active layer 207, the second-conductivity-type cladding layer 209, and the second-conductivity-type contact layer 215 may be grown in the stated order from the bottom upwards. In the third example implementation, the second-conductivity-type contact layer 215 may be an uppermost layer of the mesa structure 217.

The optical semiconductor device may include a left bank portion (first bank portion) 230a placed to the left of the mesa structure 217 in a section perpendicular to the extending direction D1, and a right bank portion (second bank portion) 230b placed to the right of the mesa structure 217 in the section. The left bank portion 230a and the right bank portion 230b each may have the same semiconductor multilayer as the semiconductor multilayer of the mesa structure 217. That is, in the left bank portion 230a and the right bank portion 230b, a part of the substrate 203, the active layer 207, the second-conductivity-type cladding layer 209, and the second-conductivity-type contact layer 215 may be grown in the stated order from the bottom upwards.

The optical semiconductor device may include a left groove portion (first groove portion) 240a placed to the left of the mesa structure 217 in the section perpendicular to the extending direction D1, and a right groove portion (second groove portion) 240b placed to the right of the mesa structure 217 in the section. The left groove portion 240a may be placed between the mesa structure 217 and the left bank portion 230a in the section perpendicular to the extending direction D1. The right groove portion 240b may be placed between the mesa structure 217 and the right bank portion 230b in the section perpendicular to the extending direction D1. Bottom portions of the left groove portion 240a and the right groove portion 240b may reach the substrate 203. In the case in which a first-conductivity-type cladding layer is placed as a separate layer as in the first example implementation, at least the bottom portions of the left groove portion 240a and the right groove portion 240b reach the first-conductivity-type cladding layer.

In the section perpendicular to the extending direction D1, a left buried layer 219a which is a semiconductor is may be placed on the left side of the mesa structure 217, and a right buried layer 219b which is a semiconductor may be placed on the right side of the mesa structure 217. The left buried layer 219a may be placed in the left groove portion 240a, and the right buried layer 219b may be placed in the right groove portion 240b. Materials and the like of the left buried layer 219a and the right buried layer 219b may be the same as in the first example implementation. As in the first example implementation, a top surface of the left buried layer 219a may include the left sloped portion Sa which slopes in the width direction D2 of the mesa structure 217 so as to be closer to the substrate 203 as the distance from the mesa structure 217 increases, and the left flat portion Fa which may be substantially parallel to the top surface of the substrate 203 and which continues to the left sloped portion Sa. Further, a top surface of the right buried layer 219b may include the right sloped portion Sb which slopes in the width direction D2 of the mesa structure 217 so as to be closer to the substrate 203 as the distance from the mesa structure 217 increases, and the right flat portion Fb which may be substantially parallel to the top surface of the substrate 203 and which continues to the right sloped portion Sb. As illustrated in FIG. 8, the left buried layer 219a and the right buried layer 219b include portions that slope downwards from top surfaces of the left bank portion 230a and the right bank portion 230b, respectively. However, in FIG. 8, only parts that have the top surface of the mesa structure 217 as a starting point are illustrated as the left sloped portion Sa and the right sloped portion Sb. Features of the left sloped portion Sa, the right sloped portion Sb, the left flat portion Fa, and the right flat portion Fb may be the same as in the first example implementation. A height of the top surface of the mesa structure 217 in the third example implementation from the substrate 203 may be lower than the height of the top surface of the mesa structure 17 in the first example implementation from the substrate 3. A thickness of the left flat portion Fa in the third example implementation in the height direction D3 may be thinner than the thickness of the left flat portion Fa in the first example implementation in the height direction D3 (the same applies to the right flat portion Fb). However, a relationship between the left sloped portion Sa (the right sloped portion Sb) and the left flat portion Fa (the right flat portion Fb) in the third example implementation may be the same as in the first example implementation.

A left insulating film 221a may be placed above the left bank portion 230a, and a right insulating film 221b may be placed above the right bank portion 230b. No parts of the left insulating film 221a and the right insulating film 221b are placed on the mesa structure 217, on the left buried layer 219a, and on the right buried layer 219b. However, as in the first example implementation, the left insulating film 221a and the right insulating film 221b may be placed on at least a part of the left buried layer 219a and a part of the right buried layer 219b, respectively. However, in that case also, it may be desired to place no parts of the left insulating film 221a and the right insulating film 221b on the left sloped portion Sa and the right sloped portion Sb as in the first example implementation.

The first electrode 211 may be placed on a wide stretch of the rear surface of the substrate 203. In the third example implementation, the first electrode 211 may be placed so as to reach both ends of the substrate 203 in the width direction D2, but is not limited thereto. The second electrode 212 may have a multilayer structure that includes at least a Au layer. For example, the second electrode 212 may have a three-layer layer structure in which layers of Ti, Pt, and Au are grown in order from a side on which the second-conductivity-type contact layer 215 is located. This configuration is merely an example. The second electrode 212 may be placed so as to cover at least the entirety of the left sloped portion Sa and the entirety of the right sloped portion Sb which sandwich the mesa structure 217. In the third example implementation, the second electrode 212 is placed so as to reach top surfaces of the left bank portion 230a and the right bank portion 230b, except for parts near the input end face and the output end face. Near the input end face and the output end face, the second electrode 212 is placed only on the mesa structure 217, in a part of the left buried layer 219a, and in a part of the right buried layer 219b. From the viewpoint of heat dissipation property, it may be desired to cover the entire region of the left sloped portion Sa and the entire region of the right sloped portion Sb with the second electrode 212. However, the second electrode 212 may be designed so as to avoid covering only parts of the left sloped portion Sa and the right sloped portion Sb that are near the end faces. It is sufficient to determine a ratio of regions in which the second electrode 212 covers the left sloped portion Sa and the right sloped portion Sb, based on a required amount of heat dissipation. For example, satisfactory heat dissipation property can be obtained when the second electrode 212 covers 80% or more of the entirety of the left sloped portion Sa and the entirety of the right sloped portion Sb. It may be more preferred for the second electrode 212 to cover 90% or more of the entirety of the left sloped portion Sa and the entirety of the right sloped portion Sb.

In the third example implementation, the left sloped portion Sa and the right sloped portion Sb are brought as close to the mesa structure 217 as possible without affecting the light distribution D as in the first example implementation. According to the third example implementation, the optical semiconductor device having an excellent heat dissipation property can thus be achieved. In the first example implementation, an uppermost surface of the optical semiconductor device is the upper surface of the mesa structure 217. In junction-down mounting in which the optical semiconductor device is mounted on a substrate with the second electrode 212 side facing the substrate, the optical semiconductor device may be mounted at an angle relative to the substrate due to upper portions of the mesa structure having a protruding shape. This problem is solvable because the left bank portion 230a and the right bank portion 230b are placed in the third example implementation. In the height direction D3, a height of a top surface of the left bank portion 230a from the substrate 203 is higher than a height of the top surface of the mesa structure 217 from the substrate 203 by a thickness of the left insulating film 221a in the height direction D3 (the same applies to the right bank portion 230b). In addition, being wider in area than the mesa structure 217, the left bank portion 230a and the right bank portion 230b can prevent the optical semiconductor device from being mounted to the substrate at an angle relative to the substrate. Although the left bank portion 230a (the right bank portion 230b) and the left groove portion 240a (the right groove portion 240b) can may have any width in the width direction D2, there is a possibility that the left buried layer 219a and the right buried layer 219b cannot be formed in a normal shape when the left groove portion 240a and the right groove portion 240b are too narrow. Accordingly, the width of the left groove portion 240a and the right groove portion 240b in the width direction D2 is preferred to be, for example, 25 times the width of the mesa structure 217 in the width direction D2, or more. The optical semiconductor device according to the third example implementation may be a semiconductor laser.

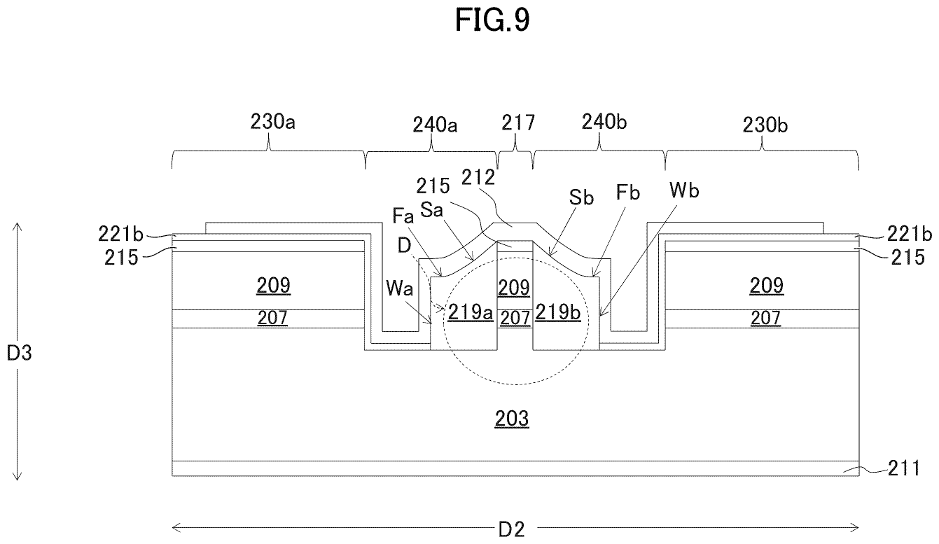

FIG. 9 is a schematic sectional view of an optical semiconductor device according to a modification example of the third example implementation that is taken along the line A-A of FIG. 7. A difference from the third example implementation is a structure in the left groove portion 240a and the right groove portion 240b.

In this modification example, the left buried layer 219a does not cover the entirety of the left groove portion 240a, and the right buried layer 219b does not cover the entirety of the right groove portion 240b. That is, the left buried layer 219a does not reach a side surface of the left bank portion 230a in the section perpendicular to the extending direction D1. The right buried layer 219b does not reach a side surface of the right bank portion 230b in the section perpendicular to the extending direction D1. The left buried layer 219a may include a left side portion (first side portion) Wa which faces the left bank portion 230a in the width direction D2 and which is spaced apart from the left bank portion 230a. The right buried layer 219b may include a right side portion (second side portion) Wb which faces the right bank portion 230b in the width direction D2 and which is spaced apart from the right bank portion 230b. The left side portion Wa and the right side portion Wb may each be positioned outside the outer edge of the light distribution D. The left insulating film 221a may be placed on a bottom surface of the left groove portion 240a and a side surface of the left bank portion 230a that is on the left groove portion 240a side. The right insulating film 221b may be placed on a bottom surface of the right groove portion 240b and a side surface of the right bank portion 230b that is on the right groove portion 240b side. The second electrode 212 may be placed so as to cover the left sloped portion Sa, the left flat portion Fa, and the left side portion Wa of the left buried layer 219a.

According to this modification example, an effect of heat dissipation from the left side portion Wa and the right side portion Wb may be obtained in addition to heat dissipation from the left sloped portion Sa and the right sloped portion Sb, and an optical semiconductor device having an even more excellent heat dissipation property may be achieved as a result.

The example implementations described above take a case in which the optical semiconductor device is a semiconductor laser and a case in which the optical semiconductor device is a semiconductor optical amplifier as examples, but the present invention is not limited thereto. For example, the optical semiconductor device may be a semiconductor modulator or a semiconductor light-receiving device. However, the amount of heat generation from the active layer is generally larger when the active layer functions as a light emission layer or an amplification layer than when the active layer functions as an absorption layer. Accordingly, the present invention is particularly effective when being applied to a semiconductor laser or a semiconductor optical amplifier. The example implementations and the modification examples may be combined with one another.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical semiconductor device, comprising:
a substrate;
a mesa structure which protrudes from the substrate and extends in an extending direction parallel to the substrate, and which includes an active layer;
a first buried layer of a semiconductor and a second buried layer of the semiconductor, the first buried layer being placed on a first side of the mesa structure in a section perpendicular to the extending direction, the second buried layer being placed on a second side of the mesa structure in the section; and
an electrode which is formed on the mesa structure and which is partially placed on the first buried layer and the second buried layer,
wherein a top surface of the first buried layer has a first sloped portion which slopes in a width direction of the mesa structure so as to be closer to the substrate as a distance from the mesa structure increases,
wherein a top surface of the second buried layer has a second sloped portion which slopes in the width direction so as to be closer to the substrate as a distance from the mesa structure increases,
wherein the electrode covers an entirety of the first sloped portion and an entirety of the second sloped portion.

2. The optical semiconductor device according to claim 1, wherein the top surface of the first buried layer further includes a first flat portion continuous to the first sloped portion.

3. The optical semiconductor device according to claim 2,
wherein the mesa structure has a conductive contact layer as an uppermost surface, and
wherein, when a gap between a top surface of the active layer and a lower surface of the conductive contact layer in a height direction of the mesa structure is given as H, the top surface of the first buried layer in the first flat portion is placed at a point that is 0H or more and 0.5H or less with the top surface of the active layer as a base point.

4. The optical semiconductor device according to claim 3, wherein the top surface of the first buried layer in the first flat portion is placed at a point that is 0.1H or more and 0.3H or less with the top surface of the active layer as a base point.

5. The optical semiconductor device according to claim 2, wherein the electrode is placed partially on the first flat portion.

6. The optical semiconductor device according to claim 2,
wherein the top surface of the first buried layer further includes a sub-flat portion continuous to a top surface of the mesa structure, and
wherein the first sloped portion continues to the sub-flat portion.

7. The optical semiconductor device according to claim 6, wherein, in the width direction, a width of the sub-flat portion is half a width of the mesa structure, or less.

8. The optical semiconductor device according to claim 2,
wherein the first buried layer further includes a first protruding portion which continues to a top surface of the mesa structure and which protrudes from the substrate, and
wherein the first sloped portion continues to the first protruding portion.

9. The optical semiconductor device according to claim 8,
wherein the mesa structure has a conductive contact layer as an uppermost surface, and
wherein the first protruding portion has a thickness less than a thickness of the conductive contact layer in a height direction of the mesa structure.

10. The optical semiconductor device according to claim 1, further comprising a first insulating film partially placed on the first buried layer,
wherein no part of the first insulating film is placed on the first sloped portion.

11. The optical semiconductor device according to claim 10,
wherein the first buried layer includes a first current block layer and a first diffusion prevention layer grown in the stated order from the substrate upwards,
wherein the electrode contains Au, and
wherein a diffusion constant of Au in the first diffusion prevention layer is smaller than a diffusion constant of Au in the first current block layer.

12. The optical semiconductor device according to claim 11,
wherein the first current block layer is formed from InP, and
wherein the first diffusion prevention layer is formed from at least one of InGaAs, InGaAsP, InGaAlAs, and InAlAs.

13. The optical semiconductor device according to claim 11, wherein the first diffusion prevention layer is an undoped layer.

14. The optical semiconductor device according to claim 1, further comprising:
a first bank portion and a second bank portion, the first bank portion being placed on the first side of the mesa structure in the section, the second bank portion being placed on the second side of the mesa structure in the section;
a first groove portion placed between the mesa structure and the first bank portion; and
a second groove portion placed between the mesa structure and the second bank portion,
wherein the first buried layer is placed in the first groove portion, and the second buried layer is placed in the second groove portion.

15. The optical semiconductor device according to claim 14, wherein a part of the electrode is placed on the mesa structure, on the first buried layer, on the second buried layer, on a part of the first bank portion, and on a part of the second bank portion, in a continuous manner.

16. The optical semiconductor device according to claim 14, further comprising a first insulating film partially placed on the first buried layer,
wherein no part of the first insulating film is placed on the mesa structure and on the first buried layer.

17. The optical semiconductor device according to claim 14,
wherein the first buried layer includes a first side portion which faces the first bank portion in the width direction, and which is spaced apart from the first bank portion, and
wherein the electrode is placed along the first side portion.

18. The optical semiconductor device according to claim 17, further comprising a first insulating film partially placed on the first buried layer,
wherein no part of the first insulating film is placed on the first side portion.

19. The optical semiconductor device according to claim 1, wherein the substrate, the first buried layer, and the second buried layer are formed from the same semiconductor material.

20. The optical semiconductor device according to claim 1, wherein the electrode covers 80% or more of the first sloped portion in the extending direction.
